(19) United States
(12) Patent Application Publication
(10) Pub. No.: US 2017/0084795 A1
(43) Pub. Date: Mar. 23, 2017

(54) METHOD AND APPARATUS FOR FORMING PHOSPHOR MATERIAL ON SURFACE OF TARGET

(71) Applicant: ACHROLUX INC., Sunnyvale, CA (US)

(72) Inventors: Peiching Ling, Sunnyvale, CA (US); Dezhong Liu, Sunnyvale, CA (US)

(21) Appl. No.: 14/856,802

(22) Filed: Sep. 17, 2015

(51) Int. Cl. H01L 33/50; B05D 1/18; H01L 33/00; B05D 1/02

(52) U.S. Cl. CPC H01L 33/502; B05D 1/02; B05D 1/18; H01L 33/00; H01L 2933/0041

(57) ABSTRACT

A method for forming a phosphor material on a surface of a target is provided, which includes the steps of: providing a chamber for receiving the phosphor material constituted by a plurality of particles, wherein a grid is disposed on or beneath a surface constituted by the phosphor material in the chamber, and the grid has a plurality of fine lines S_{N} each having opposite first and second ends, N being a positive integer greater than 1; exposing the surface of the target to the phosphor material; and creating a charge on the plurality of particles, generating an electric field between the chamber and the surface of the target and oscillating the plurality of fine lines, so as to drive the plurality of particles toward the surface of the target and to be deposited on the surface of the target.

### BACKGROUND OF THE INVENTION

1. Field of the Invention

The present invention relates to methods for forming a phosphor material on a surface of a target, and more particularly, to a method and an apparatus for forming a uniform coating for converting the wavelength of LED light.

2. Description of Related Art

The present invention generally relates to material manufacturing and optical equipment technologies. Embodiments of the present invention provide a method and a system for forming a uniform material layer, which can be used in optical devices. For example, the uniform material layer can serve as a phosphorous layer in the lens of an LED device. The term “phosphor” used herein refers to any luminescent material, which absorbs light of one wavelength and emits light of a different wavelength. As used herein, the terms “phosphor” and “wavelength-conversion material” can be used interchangeably.

Phosphors have been widely used in the productions of white-light LED packages or various blue pump LEDs (for example, yellow or red colors converted by phosphors) for producing light colors. The conventional methods for depositing phosphors on a blue LED die or package include:

slurry method: phosphor particles are dispersed throughout a silicone resin, an epoxy resin or a solvent filler material, to form a mixture of phosphors, which is applied to an LED surface or the lens material of a package by various technologies such as spray-coating, dip-coating, dispensing, phosphors in a container, or molding on a support structure; and

electrophoretic deposition (EPD): phosphor particles are dispersed throughout an electrochemical solution, and then deposited on an LED wafer by a bias voltage bridging over the LED wafer and the electrochemical solution.

The above conventional methods have a difference in the uniformity of thickness across an LED surface or the interior of an LED package. The slurry method usually forms a particle layer with uneven thickness, leading to inconsistent light spots of an LED and poor LED color uniformity as converted by phosphors. Moreover, it is difficult to use these conventional methods on a non-planar surface to form a uniform phosphorous layer, such that these conventional methods face big challenges in satisfying the requirements of lighting applications.

Accordingly, it is an important issue to form a uniform phosphor material.

### SUMMARY OF THE INVENTION

The present invention provides a method for forming a phosphor material on a surface of a target, which comprises the steps of providing a chamber for receiving the phosphor material comprised of a plurality of particles, wherein a grid is disposed on or beneath a surface constituted by the phosphor material in the chamber, and the grid has a plurality of fine lines S_{N} each having opposite first and second ends, N being a positive integer greater than 1; exposing the surface of the target to the phosphor material; and creating a charge on the plurality of particles, generating an electric field between the chamber and the surface of the target, and oscillating the plurality of fine lines, such that the plurality of particles are driven toward the surface of the target and deposited on the surface of the target.

In an embodiment, the surface of the target is exposed over the phosphor material.

In an embodiment, the electric field is generated between the surface of the target and the grid. Moreover, the grid has electrical conductivity. Furthermore, the method further comprises the step of driving the grid with a horizontal or vertical reciprocating motion on the surface constituted by the phosphor material.

In an embodiment, in order to adjust the oscillation frequency of the fine lines, the grid comprises a frame and a tension adjustment mechanism corresponding to each of the fine lines and disposed on the frame, wherein the fine line is fixed to the tension adjustment mechanism. In another embodiment, each of the fine lines is provided with at least a tension adjustment mechanism. As such, the first end of the fine line can be directly fixed to the grid and the second end of the fine line can be fixed to the tension adjustment mechanism.

In a further embodiment, the tension adjustment mechanism comprises: at least a support portion allowing the fine line to extend thereacross; and a movable abutting member abutting against the fine line. The movable abutting member can be a sliding or rotating member movably disposed on the support portion

To oscillate the plurality of fine lines, the first ends of odd-numbered fine lines and the second ends of even-numbered fine lines can be plucked.

In another embodiment, the odd-numbered fine lines and the even-numbered fine lines are offset from one another in a length direction.

The present invention further provides an apparatus for implementing the method of the present invention. The apparatus comprises a holder for holding the target; a chamber disposed beneath the holder for receiving the phosphor material; a grid disposed on or beneath a surface constituted by the phosphor material and having a plurality of fine lines S_{N} each having opposite first and second ends, wherein N is a positive integer greater than 1; and a voltage power supply electrically connected to the grid for creating a charge on the phosphor material and generating an electric field between the chamber and the surface of the target, so as to deposit the phosphor material on the surface of the target.

In the present invention, the target can be a lens, a lens forming mold, an LED die, glass, film, metal etc.

Further, the plurality of particles can be phosphor particles, binder particles, a mixture of the phosphor particles and binder particles, or in the form of phosphor particles covered with a binder material.

In the apparatus of the present invention, the voltage power supply can comprise a voltage supply element electrically connected to the grid; a conversion element electrically connected to the voltage supply element; and a controller for controlling the conversion element.

In an embodiment, the apparatus of the present invention further comprises a conductive element disposed beneath the chamber, and electrically connected to the voltage power supply to perform potential oscillation.

In an embodiment, the apparatus of the present invention further comprises a reciprocation driving mechanism for driving the grid with a reciprocating motion.

The method of the present invention drives the plurality of particles toward the surface of the target and to be deposited on the surface of the target, by creating a charge on the plurality of particles and generating an electric field between the chamber and the surface of the target. Further, through oscillation of the plurality of fine lines of the grid, the plurality of particles are loosed or driven to be dispersed in the chamber. Hence, the thickness of the particles are extremely thin and uniform after stacking.

### BRIEF DESCRIPTION OF DRAWINGS

FIGS. 1A and 1B are schematic diagrams showing LED lens structures;

FIG. 1C is a schematic diagram showing an array of LED assemblies;

FIG. 2A is a schematic diagram showing a homogenous LED phosphorous layer formed on convex surfaces of a male lens forming mold in accordance with the method of the present invention;

FIG. 2B is a schematic diagram showing a homogenous LED phosphorous layer formed on concave surfaces of a female lens forming mold in accordance with the method of the present invention;

FIGS. 2C and 2D are schematic diagrams showing homogenous LED phosphorous layers formed on flat surfaces and arculate surfaces of the male lens forming mold and the female lens forming mold according to the present invention;

FIGS. 3A and 3B are schematic diagrams showing homogenous LED phosphorous layers formed on LED dice according to the present invention;

FIG. 4A is a schematic diagram showing an apparatus for forming a phosphor material according to the present invention;

FIG. 4B is a schematic diagram showing an apparatus for forming a phosphor material according to the present invention, wherein the apparatus has a pan having a porous structure;

FIG. 5A is a schematic diagram of a grid of the present invention;

FIG. 5B is a schematic diagram of a circular-shaped grid;

FIG. 5C is a schematic cross-sectional diagram taken along a sectional line C-C of FIG. 5A, wherein the grid has a tension adjustment mechanism;

FIG. 5D is a schematic diagram showing non-aligned fixing points of fine lines on a frame;

FIGS. 5E and 5E′ are schematic diagrams of the fine lines mounted with loads;

FIG. 6 is a schematic flow diagram showing a method for forming a phosphor material on a surface of a target according to the present invention; and

FIG. 7 is a schematic diagram showing a direct voltage supply in the establishment of an electric field according to the present invention.

### DETAILED DESCRIPTION OF PREFERRED EMBODIMENTS

In the following, specific embodiments are provided to illustrate the detailed description of the present invention. Those skilled in the art can easily conceive the other advantages and effects of the present invention, based on the disclosure of the specification. The present invention can also be carried out or applied by other different embodiments. Each of the details in the specification of the present invention can also be modified or altered in view of different viewpoints and applications, without departing from the spirit of the present invention.

The structures, proportions, and sizes illustrated in the appended drawings of the specification of the present invention are merely for coping with the disclosure of the specification, in order to allow those skilled in the art to conceive and peruse it. The drawings are not for constraining the limitations of the present invention, such that they do not have any technical significance. Any structural modifications, alterations of proportions and adjustments of sizes, as long as not affecting the effect brought about by the present invention and the purpose achieved by the present invention, should fall within the range encompassed by the technical content disclosed in the present invention. At the same time, the language used in the specification of the present invention is merely for the clarity of expression, and not intended to limit the scope of the present invention. The alterations or adjustments of the relative relationships, while not substantially altering the technical content, can also be regarded as fallen within the scope of the present invention.

According to the method of the present invention, a homogenous coating can be formed on an LED unit or an array constituted by a plurality of LED units. For example, a phosphor material or a phosphorous layer can be formed on a surface of a target.

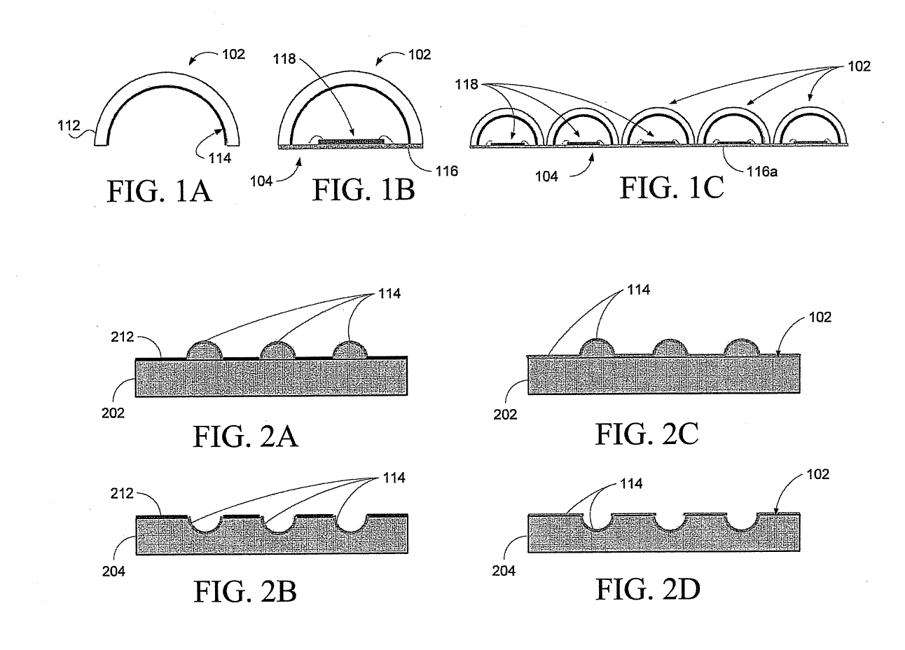

The homogenous coating can be formed on any suitable surface. For example, referring to FIGS. 1A and 1B, an LED lens structure 102 includes a lens element 112 and a homogenous LED phosphorous layer 114 formed on an inner surface of the lens element 112.

FIG. 1B shows that the LED lens structure 102 is mounted onto an LED assembly 104, which includes a board 116 and an LED die 118. FIG. 1C is a schematic diagram showing an array of LED units 104.

Referring to FIG. 2A, the homogenous LED phosphorous layer 114 is formed, in accordance with the method of the present invention, on any convex surfaces of a male lens forming mold 202, wherein the homogenous LED phosphorous layer 114 can only be formed on the convex surfaces of the male lens forming mold 202 by the use of a protection mask 212.

Similarly, referring to FIG. 2B, the homogenous LED phosphorous layer 114 can be formed on the concave surfaces of a female lens forming mold 204.

FIGS. 2C and 2D show that the homogeneous LED phosphorous layer 114 is formed on the flat surfaces and arculate surfaces of the male lens forming mold 202 and female lens forming mold 204, respectively.

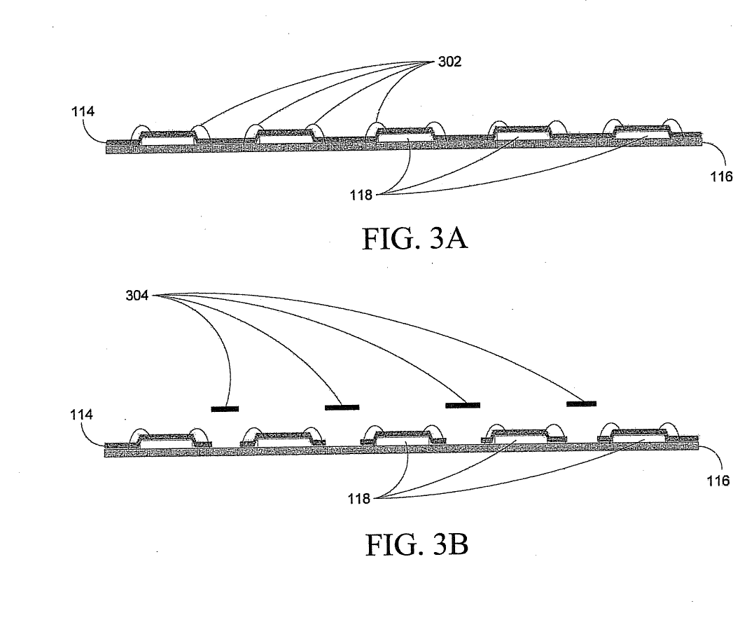

FIGS. 3A and 3B show that the homogenous LED phosphorous layer 114 is formed on a plurality of LED dice 118, and the plurality of LED units 104 having the LED dice 118 are in an array configuration, wherein bonding wires 302 are electrically connected to the board 116. Moreover, referring to FIG. 3B, a mask 304 can be used to prevent the formation of the homogenous LED phosphorous layer 114 on certain areas.

Referring to FIGS. 1 to 3, the target described in the present invention can be a lens, a lens forming mold or an LED die. Also, the target of the present invention can be glass, film, metal etc.

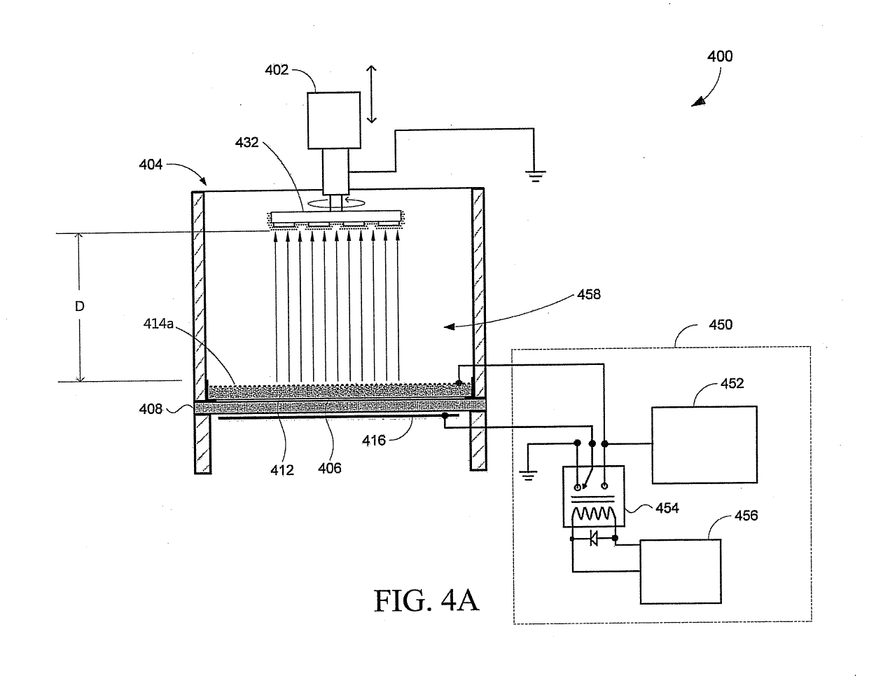

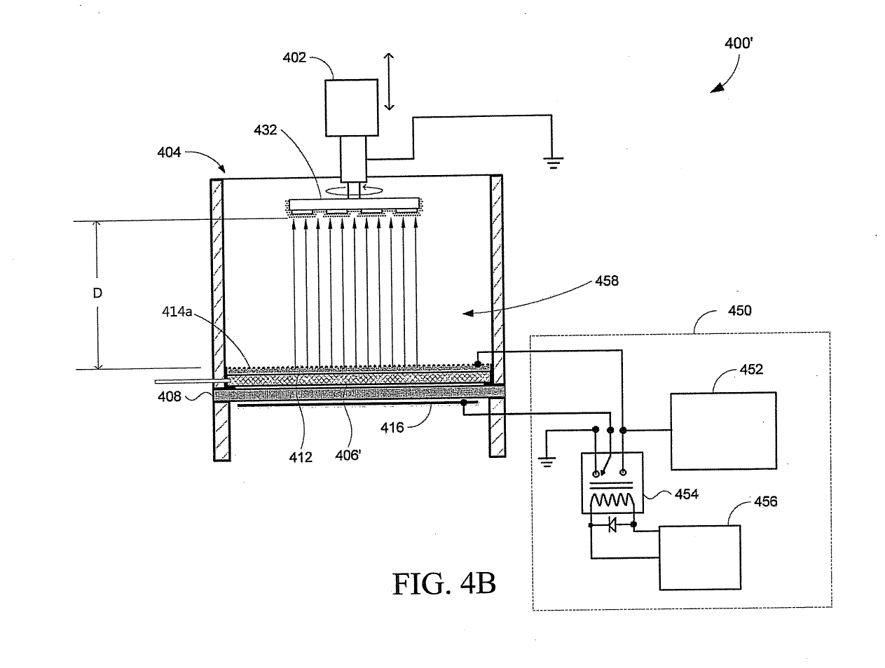

Referring to FIG. 4, an apparatus 400 for forming a phosphor material according to the present invention is illustrated. The apparatus 400 includes a holder 402, a chamber 404, a grid 414a and a voltage power supply 450.

The holder 402 is used for holding a target 432. For example, the holder 402 has clamps or a suction element for holding the target 432. On the other hand, the holder 402 can be equipped with a driving unit, such as a motor, to revolve the target 432 or to drive the target 432 toward the interior of the chamber 404, so as to expose the surface of the target 432 to the phosphor material. For example, the target 432 can revolve at one and half to several revolutions per minute.

Moreover, the target 432 can be grounded by, for example, allowing the holder 402 to be grounded in the method of the present invention.

The chamber 404 can be made of non-conductive materials, such as plastic materials, for example, nylon, Plexiglas®, etc.

The chamber 404 can have a pan 406 for receiving or loading a phosphor material 412. Moreover, the phosphor material is constituted by a plurality of particles, which are phosphor particles, binder particles, a mixture of the phosphor particles and the binder particles, or phosphor particles covered with a binder material. That is, the phosphor material is powder. Further, in addition to being phosphor powder, the phosphor material can be quantum dot powders, such as red or green quantum dot powders.

In the method of the present invention, the surface of the target 432 is exposed over the phosphor material 412. In one example, the target 432 is spaced apart from the pan 406 or the phosphor material 412 by a separation distance D, which is, for example, from 100 mm to 250 mm.

Referring to FIG. 4A, the grid 414a is disposed on the surface constituted by the phosphor material 412 or buried beneath the surface constituted by the phosphor material 412.

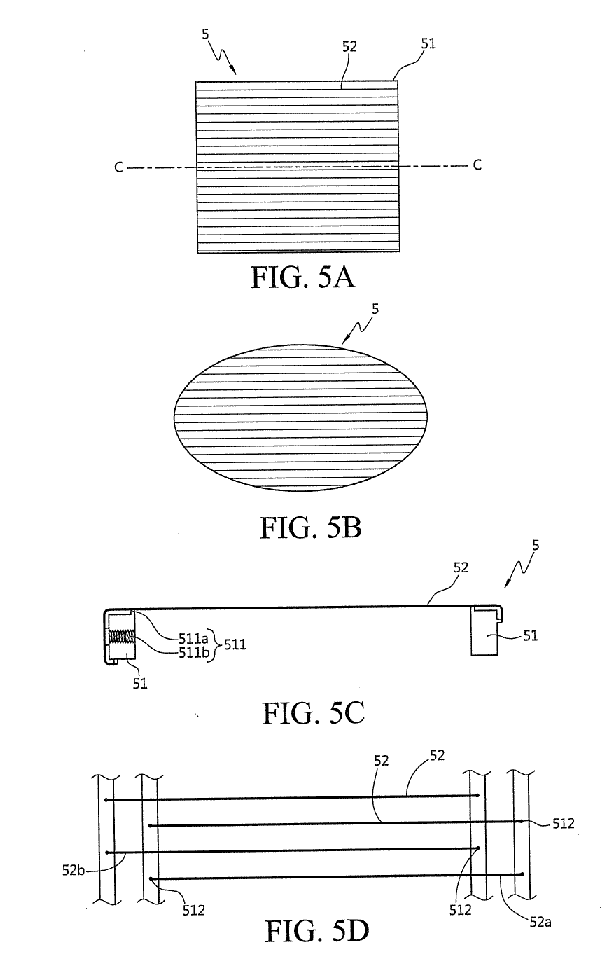

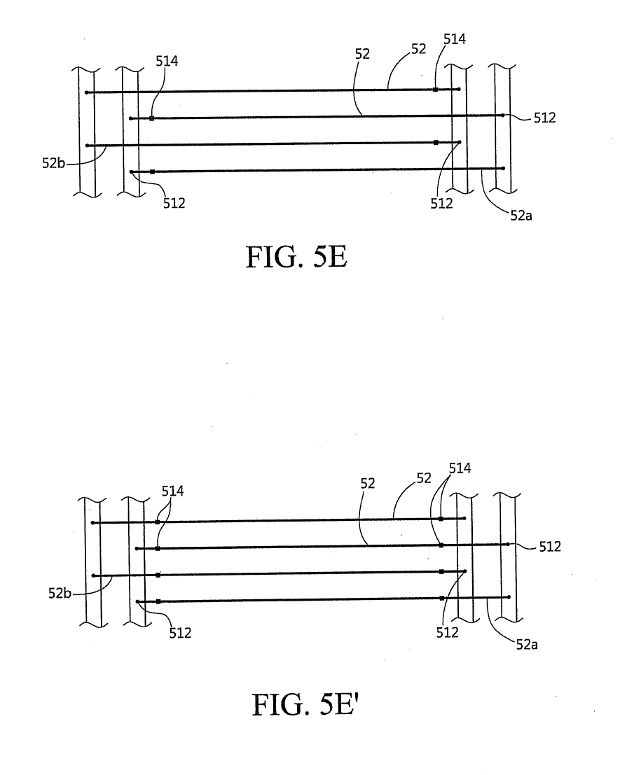

Referring to FIG. 5A, the grid 5 has a frame 51 and a plurality of parallel fine lines 52 fixed to the frame 51. The parallel fine lines 52 are separated from one another by a distance ranging (but not limited to) from 5 mm to 10 mm.

Moreover, referring to FIG. 5B, the grid 5 can have a circular shape.

Further, the grid is electrically conductive, and hence the fine lines are metal lines or fine lines covered with metal. Moreover, the appearance of the grid is not particularly limited. However, the grid is preferably rectangular, which facilitates the consistency in the oscillation frequency of each of the fine lines.

FIG. 5C is a schematic cross-sectional diagram taken along a section line C-C of FIG. 5A. Referring to FIG. 5C, the grid 5 further has a tension adjustment mechanism 511 corresponding to each of the fine lines 52 and disposed on the frame 51. The fine line 52 is fixed to the tension adjustment mechanism 511. The tension adjustment mechanism 511 has at least a support portion 511a allowing the fine line 52 to extend thereacross, and a movable abutting member 511b abutting against the fine line 52. The movable abutting member 511b is a sliding or rotating member (for example, a screw in the drawing) movably disposed on the support portion 511a.

Referring to FIG. 5D, fixing points 512 of the fine lines 52 on the frame 51 are not aligned with one another. For example, odd-numbered fine lines 52 and even-numbered fine lines 52 are offset from one another in a length direction, such that opposite first and second ends of the fine lines have similar oscillation amplitudes.

Moreover, the grid can be disposed on the surface constituted by the phosphor material or buried beneath the surface constituted by the phosphor material.

Further, referring to FIG. 5E, in the embodiments of the method and apparatus for forming a phosphor material on a surface of a target, each of the fine lines 52 is mounted with at least a load 514. The load can be only an object heavier than the fine line 52, for example, a weight or any other block. The load can also be an oscillator for oscillating the fine line 52.

Referring to FIG. 5E′, each of two opposite sides of each of the fine lines 52 is mounted with a load 514.

Referring again to FIG. 4A, the apparatus for forming a phosphor material further includes a conductive element 416 disposed beneath the chamber 404. The conductive element 416 is electrically connected to the voltage power supply 450 to perform potential oscillation. In one embodiment, the conductive element 416 can be a conductive plate. The conductive plate or board can compensate the height of the phosphor material 412 in the pan 406 after oscillation, thus leading to more uniform distribution of the oscillated phosphor material 412 in the air. Moreover, the grid 414a and the conductive element 416 are electrically insulated or isolated. For example, an insulator 408 of the chamber 404 can be used to insulate the conductive element 416 from the pan 406, so as to achieve electrical insulation or electrical isolation between the grid 414a and the conductive element 415. The insulator 408 can be nylon, Teflon® or other insulating materials.

The voltage power supply 450 is electrically connected to the grid 414a, so as to create a charge on the phosphor material 412, and generate an electric filed 458 between the chamber 404 and the surface of the target 432 to facilitate the deposition of the phosphor material on the surface of the target 432. The voltage power supply 450 includes a voltage supply element 452 electrically connected to the grid 414a; a conversion element 454 electrically connected to the voltage supply element 452; and a controller 456 for controlling the conversion element 454 to change the voltage potential outputted by the voltage supply element 452.

Furthermore, the conductive element 416 is also electrically connected to the voltage supply element 450. In an example, the conductive element 416 is also electrically connected to the conversion element 454.

The voltage supply element 452 provides adjustable voltages, such as direct voltages from 10 kV to 80 kV.

In addition to being electrically connected to the voltage supply element 452, the conversion element 454 can also be grounded. That is, the conversion element 454 can be switched between being grounded and the power supply element 452.

The controller 456 switches at a frequency of 50 to 90 cycles per minute with a 50% duty cycle, but other frequencies may also be used.

In operation, the target 432, being electrically connected to a ground potential, serves as an anode. The grid 414a serves as a cathode. The conductive element 416 switches between the ground voltage and the voltage supplied by the voltage supply element 452. When the potential of the conductive element 416 changes between the ground potential and the voltage supplied by the voltage supply element 452, an electric field 458 is generated between the anode and the cathode. Further, the voltage applied on the grid 414a creates a charge on the phosphor material 412. In other words, a charge is created on the plurality of particles, so as to drive the plurality of particles toward the surface of the target 432 and cover the surface of the target 432, thereby forming the homogenous phosphorous layer 114.

Referring to FIG. 4B, in order to uniformly distribute the phosphor material 412 in the pan 406′, thereby facilitating the plurality of particles to move consistently with electric field lines, the pan 406′ of the apparatus 400′ can have a porous structure, into which a small amount of air is permitted to pass, and then escapes through the upper surface of the pan 406′. Thus, the plurality of particles would be loosed without becoming airborne. In one embodiment, the pan 406′ can be a porous bed.

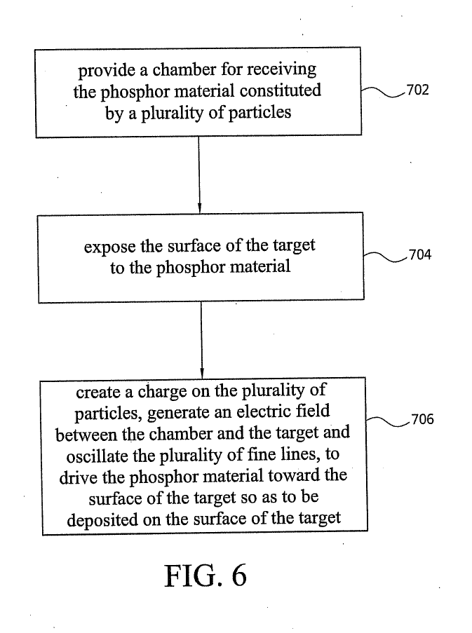

Referring to FIG. 6, the method for forming a phosphor material on a surface of a target of the present invention includes: in step 702, providing a chamber for receiving the phosphor material, wherein the phosphor material is constituted by a plurality of particles; in step 704, exposing the surface of the target to the phosphor material; and in step 706, creating a charge on the plurality of particles, generating an electric field between the chamber and the surface of the target, and oscillating the plurality of fine lines, so as to drive the plurality of particles toward the surface of the target and to be deposited on the surface of the target.

It should be appreciated that the method illustrated in FIG. 6 can be repeated, in order to obtain a multi-layered structure, for example, a formed phosphor material layer with various colors of light, or a layer constituted by binder particles.

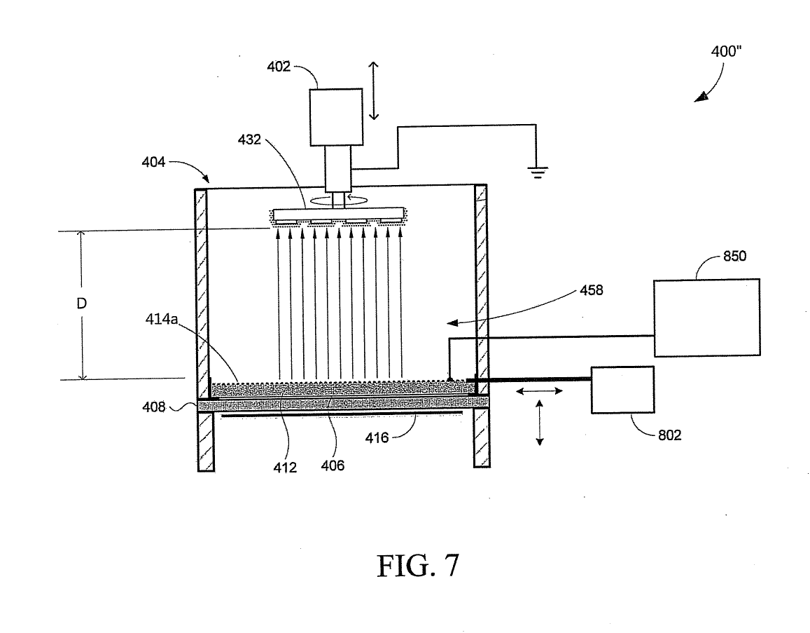

The voltage power supply 450 shown in FIG. 4 can be a direct power source. As shown in FIG. 7, the direct voltage supply 850 can be used to establish an electric field. Moreover, the apparatus 400″ for forming a phosphor material can further include a reciprocation driving mechanism 802 for driving the grid 414a with a reciprocating motion and further causing the plurality of fine lines to oscillate. The reciprocating motion may be a horizontal or vertical movement as shown in FIG. 8. At the same time, an electric field is also generated between the grid 414a and the target 432, so as to create a charge on the plurality of particles, and thus to drive the plurality of particles toward the surface of the target and to be deposited on the surface of the target.

In one embodiment, the frequency of the reciprocating motion is from 30 to 90 cycles per minute, but other frequencies can also be used.

Further, the reciprocation driving mechanism 802 can have a plurality of pulling members for plucking the plurality of fine lines. For example, referring to FIG. 5D, the odd-numbered fine lines 52 and the even-numbered fine lines 52 are offset from one another in the length direction. As such, to oscillate the fine lines, the first ends 52a of the odd-numbered fine lines and the second ends 52b of the even-numbered fine lines are plucked.

According to the method of the present invention, the phosphor material in the chamber moves to the surface of the target due to the generation of an electric field, instead of using a flow of air to carry the phosphor material. Thus, the phosphor material is not influenced by the turbulent of the airflow.

The above examples are only used to illustrate the principle of the present invention and the effect thereof, and should not be construed as to limit the present invention. The above examples can all be modified and altered by those skilled in the art, without departing from the spirit and scope of the present invention as defined in the following appended claims.

What is claimed is:

1. A method for forming a phosphor material on a surface of a target, comprising the steps of:
providing a chamber for receiving the phosphor material constituted by a plurality of particles, wherein a grid is disposed on or beneath a surface constituted by the phosphor material in the chamber, and the grid has a plurality of fine lines S_{N} each having opposite first and second ends, N being a positive integer greater than 1;
exposing the surface of the target to the phosphor material; and
creating a charge on the plurality of particles, generating an electric field between the chamber and the surface of the target, and oscillating the plurality of fine lines, so as to drive the plurality of particles toward the surface of the target and to be deposited on the surface of the target.

2. The method of claim 1, wherein the surface of the target is exposed over the phosphor material.

3. The method of claim 1, wherein the electric filed is generated between the surface of the target and the grid.

4. The method of claim 1, wherein the grid has electrical conductivity.

5. The method of claim 1, wherein the target is selected from the group consisting of a lens, a lens forming mold, an LED die, glass, film and metal.

6. The method of claim 1, wherein the plurality of particles are selected from the group consisting of phosphor particles, binder particles, a mixture of the phosphor particles and the binder particles, and phosphor particles covered with a binder material.

7. The method of claim 1, wherein the grid comprises a frame and a tension adjustment mechanism corresponding to each of the fine lines and disposed on the frame, the fine line being fixed to the tension adjustment mechanism.

8. The method of claim 7, wherein the tension adjustment mechanism comprises:
at least a support portion allowing the fine line to extend thereacross; and
a movable abutting member abutting against the fine line.

9. The method of claim 8, wherein the movable abutting member is a sliding or rotating member movably disposed on the support portion.

10. The method of claim 1, wherein to oscillate the plurality of fine lines, the first ends of odd-numbered fine lines and the second ends of even-numbered fine lines are plucked.

11. The method of claim 1, wherein odd-numbered fine lines and even-numbered fine lines are offset from one another in a length direction.

12. The method of claim 1, wherein each of the fine lines is mounted with at least a load.

13. The method of claim 1, wherein each of two opposite sides of each of the fine lines is mounted with a load.

14. An apparatus for forming a phosphor material on a surface of a target, comprising:
a holder for holding the target;
a chamber disposed beneath the holder for receiving the phosphor material;
a grid disposed on or beneath a surface constituted by the phosphor material and having a plurality of fine lines S_{N} each having opposite first and second ends, wherein N is a positive integer greater than 1; and
a voltage power supply electrically connected to the grid for creating a charge on the phosphor material and generating an electric field between the chamber and the surface of the target, so as to deposit the phosphor material on the surface of the target.

15. The apparatus of claim 14, wherein the voltage power supply comprises:
a voltage supply element electrically connected to the grid;
a conversion element electrically connected to the voltage supply element; and
a controller for controlling the conversion element.

16. The apparatus of claim 14, further comprising a conductive element disposed beneath the chamber, and electrically connected to the voltage power supply to perform potential oscillation.

17. The apparatus of claim 14, further comprising a reciprocation driving mechanism for driving the grid with a reciprocating motion.

18. The apparatus of claim 14, wherein the grid comprises a frame and a tension adjustment mechanism corresponding to each of the fine lines and disposed on the frame, the fine line being fixed to the tension adjustment mechanism.

19. The apparatus of claim 18, wherein the tension adjustment mechanism comprises:
at least a support portion allowing the fine line to extend thereacross; and
a movable abutting member abutting against the fine line.

20. The apparatus of claim 19, wherein the movable abutting member is a sliding or rotating member movably disposed on the support portion.

21. The apparatus of claim 14, wherein odd-numbered fine lines and even-numbered fine lines are offset from one another in a length direction.

22. The apparatus of claim 14, wherein each of the fine lines is mounted with at least a load.

23. The apparatus of claim 14, wherein each of two opposite sides of each of the fine lines is mounted with a load.
